(19) United States
(12) Patent Application Publication
(10) Pub. No.: US 2025/0357136 A1
(43) Pub. Date: Nov. 20, 2025

(54) ETCHING METHOD AND PLASMA PROCESSING APPARATUS

(71) Applicant: Tokyo Electron Limited, Tokyo (JP)

(72) Inventor: Koki MUKAIYAMA, Kurokawa-gun (JP)

(21) Appl. No.: 19/291,186

(22) Filed: Aug. 5, 2025

Related U.S. Application Data
(63) Continuation of application No. PCT/JP2024/000496, filed on Jan. 11, 2024.

(30) Foreign Application Priority Data
Feb. 13, 2023 (JP) 2023-020225

(51) Int. Cl. H01L 21/311; H01J 37/32

(52) U.S. Cl. CPC H01L 21/31122; H01J 37/32449; H01L 21/31144; H01J 2237/334

(57) ABSTRACT

In one exemplary embodiment, an etching method is provided. This method includes (a) providing a substrate on a substrate support in a chamber, the substrate having a carbon-containing film and a mask on the carbon-containing film; and (b) etching the carbon-containing film using plasma formed from a first processing gas, the first processing gas containing a phosphorus halide gas, an oxygen-containing gas, and a sulfur-containing gas, or containing the phosphorus halide gas and an oxygen- and sulfur-containing gas.

### CROSS-REFERENCE TO RELATED APPLICATION

The present application claims priority under 35 U.S.C. § 119 to Japanese Patent Application No. 2023-020225 filed on Feb. 13, 2023, and PCT Application No. PCT/JP2024/000496 filed on Jan. 11, 2024, the entire contents of which are incorporated herein by reference.

### BACKGROUND

### Field

An exemplary embodiment of the present disclosure relates to an etching method and a plasma processing apparatus.

### Description of Related Art

JP2018-200925 A discloses a technique of etching an organic film using O₂ gas and COS gas.

### SUMMARY

In one exemplary embodiment of the present disclosure, there is provided an etching method, including: (a) providing a substrate on a substrate support in a chamber, the substrate having a carbon-containing film and a mask on the carbon-containing film; and (b) etching the carbon-containing film using plasma formed from a first processing gas, the first processing gas containing a phosphorus halide gas, an oxygen-containing gas, and a sulfur-containing gas, or containing the phosphorus halide gas and an oxygen- and sulfur-containing gas.

### BRIEF DESCRIPTION OF DRAWINGS

FIG. 1 is a diagram for describing a configuration example of a plasma processing apparatus.

FIG. 2 is a diagram for describing a configuration example of an inductively coupled plasma processing apparatus.

FIG. 3 is a diagram for describing an example of opening blockage.

FIG. 4 is a flowchart related to a first embodiment.

FIG. 5 is a diagram illustrating an example of a cross-sectional structure of a substrate W provided in step ST11.

FIG. 6 is a diagram for describing an example of a phenomenon occurring in step ST12.

FIG. 7 is a flowchart related to a second embodiment.

FIG. 8 is a diagram for describing an example of a phenomenon that occurs in a repeated cycle of step ST22 and step ST23.

FIG. 9 is a flowchart related to a change example of the second embodiment.

FIG. 10 is a flowchart related to a modification example of the second embodiment.

FIG. 11 is a diagram illustrating results of etching related to Example 1 and Reference Example 1.

FIG. 12 is a diagram illustrating results of etching related to Example 2 and Reference Example 1.

FIG. 13 is a diagram illustrating results of etching related to according to Example 2 and Reference Example 1.

### DETAILED DESCRIPTION

Hereinafter, each embodiment of the present disclosure will be described.

In one exemplary embodiment, there is provided an etching method, including: (a) providing a substrate on a substrate support in a chamber, the substrate having a carbon-containing film and a mask on the carbon-containing film; and (b) etching the carbon-containing film using plasma formed from a first processing gas, the first processing gas containing a phosphorus halide gas, an oxygen-containing gas, and a sulfur-containing gas, or containing the phosphorus halide gas and an oxygen- and sulfur-containing gas.

In one exemplary embodiment, the etching method further including: (c) etching the carbon-containing film using plasma formed from a second processing gas different from the first processing gas, the second processing gas containing the oxygen-containing gas and the sulfur-containing gas, or containing the oxygen- and sulfur-containing gas.

In one exemplary embodiment, the second processing gas does not include the phosphorus halide gas.

In one exemplary embodiment, the second processing gas includes the phosphorus halide gas at a flow rate lower than a flow rate of the phosphorus halide gas included in the first processing gas.

In one exemplary embodiment, a ratio of an execution time of the etching in the (c) to an execution time of the etching in the (b) is 0.8 or more and 1.2 or less.

In one exemplary embodiment, a cycle including the (b) and the (c) is repeated a plurality of times.

In one exemplary embodiment, in at least one cycle of a second or subsequent cycles, a ratio of an execution time of the etching in the (c) to an execution time of the etching in the (b) is larger than the ratio in a first cycle.

In one exemplary embodiment, a temperature of the substrate support in at least one cycle of a second or subsequent cycles is set to be higher than a temperature of the substrate support in a first cycle.

In one exemplary embodiment, the phosphorus halide gas includes at least one gas selected from the group consisting of a fluorine halide gas, a chlorine halide gas, an oxyfluorine halide gas, and an oxychlorine halide gas.

In one exemplary embodiment, the phosphorus halide gas includes at least one gas selected from the group consisting of a PF₃ gas, a PF₅ gas, and a PCl₃ gas.

In one exemplary embodiment, in the first processing gas, a flow rate of the phosphorus halide gas is 5 vol % or less of a total flow rate of the first processing gas.

In one exemplary embodiment, the oxygen-containing gas includes at least one gas selected from the group consisting of an O₂ gas, a CO gas, and a CO₂ gas.

In one exemplary embodiment, the oxygen- and sulfur-containing gas is at least one of a COS gas and an SO₂ gas.

In one exemplary embodiment, the sulfur-containing gas is an SF₆ gas.

In one exemplary embodiment, the mask includes a silicon-containing film or a metal-containing film.

In one exemplary embodiment, the carbon-containing film includes an amorphous carbon film.

In one exemplary embodiment, in the (b), a temperature of the substrate support is set to 0° C. or lower.

In one exemplary embodiment, in the (c), a temperature of the substrate support is set to 0° C. or lower.

In one exemplary embodiment, there is provided a plasma processing apparatus, including: a chamber; and a controller, in which the controller is configured to execute (a) providing a substrate on a substrate support in a chamber, the substrate having a carbon-containing film and a mask on the carbon-containing film, and (b) controlling of etching the carbon-containing film using plasma formed from a first processing gas, the first processing gas containing a phosphorus halide gas, an oxygen-containing gas, and a sulfur-containing gas, or containing the phosphorus halide gas and an oxygen- and sulfur-containing gas.

In one exemplary embodiment, the controller is configured to further execute (c) etching the carbon-containing film using plasma formed from a second processing gas different from the first processing gas, the second processing gas containing the oxygen-containing gas and the sulfur-containing gas, or containing the oxygen- and sulfur-containing gas.

Hereinafter, each embodiment of the present disclosure will be described in detail with reference to the drawings. In each drawing, the same or similar elements will be given the same reference numerals, and repeated descriptions will be omitted. Unless otherwise specified, a positional relationship such as up, down, left, and right will be described based on a positional relationship illustrated in the drawings. A dimensional ratio in the drawings does not indicate an actual ratio, and the actual ratio is not limited to the ratio illustrated in the drawings.

### <Configuration Example of Plasma Processing Apparatus>

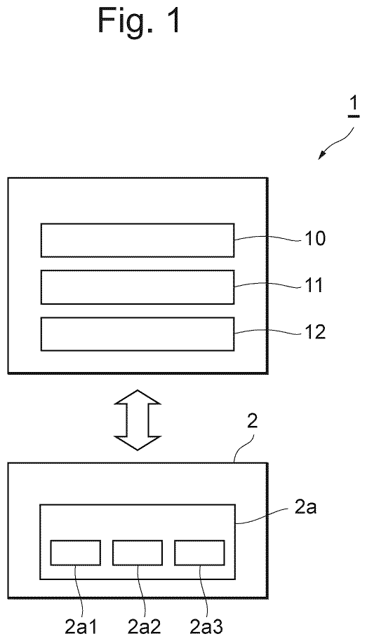

FIG. 1 is a diagram for describing a configuration example of a plasma processing apparatus. In an embodiment, a plasma processing apparatus 1 is an example of a substrate processing apparatus. The plasma processing apparatus 1 includes a controller 2, a plasma processing chamber 10, a substrate support 11, and a plasma generator 12. The plasma processing chamber 10 has a plasma processing space. In addition, the plasma processing chamber 10 has at least one gas supply port for supplying at least one processing gas to the plasma processing space, and at least one gas exhaust port for exhausting the gas from the plasma processing space. The gas supply port is connected to a gas supply 20, described later, and the gas exhaust port is connected to an exhaust system 40, described later. The substrate support 11 is disposed in the plasma processing space and has a substrate support surface for supporting a substrate.

The plasma generator 12 is configured to form plasma from at least one processing gas supplied into the plasma processing space. The plasma formed in the plasma processing space may be a capacitively coupled plasma (CCP), an inductively coupled plasma (ICP), an electron-cyclotron-resonance plasma (ECR plasma), a helicon wave plasma (HWP), a surface wave plasma (SWP), or the like. Further, various types of plasma generators including an alternating current (AC) plasma generator and a direct current (DC) plasma generator may be used. In an embodiment, an AC signal (AC power) used in the AC plasma generator has a frequency in the range of 100 kHz to 10 GHz. Therefore, the AC signal includes a radio frequency (RF) signal and a microwave signal. In an embodiment, the RF signal has a frequency in the range of 100 kHz to 150 MHz.

The controller 2 processes a computer-executable instruction that causes the plasma processing apparatus 1 to execute various steps described in the present disclosure. The controller 2 may be configured to control each element of the plasma processing apparatus 1 to execute the various steps described here. In an embodiment, a part or all of the controller 2 may be configured as a system outside the plasma processing apparatus 1. The controller 2 may include a processor 2a1, a storage 2a2, and a communication interface 2a3. The controller 2 is realized by, for example, a computer 2a. The processor 2a1 may be configured to read out a program from the storage 2a2 and to execute the read-out program to perform various control operations. This program may be stored in the storage 2a2 in advance, or may be acquired through a medium when necessary. The acquired program is stored in the storage 2a2, is read out from the storage 2a2, and executed by the processor 2a1. The medium may be various storage media readable by the computer 2a or may be a communication line connected to the communication interface 2a3. The processor 2a1 may be a central processing unit (CPU). The storage 2a2 may include a random access memory (RAM), a read only memory (ROM), a hard disk drive (HDD), a solid state drive (SSD), or a combination thereof. The communication interface 2a3 may communicate with each element of the plasma processing apparatus 1 via a communication line such as a local area network (LAN).

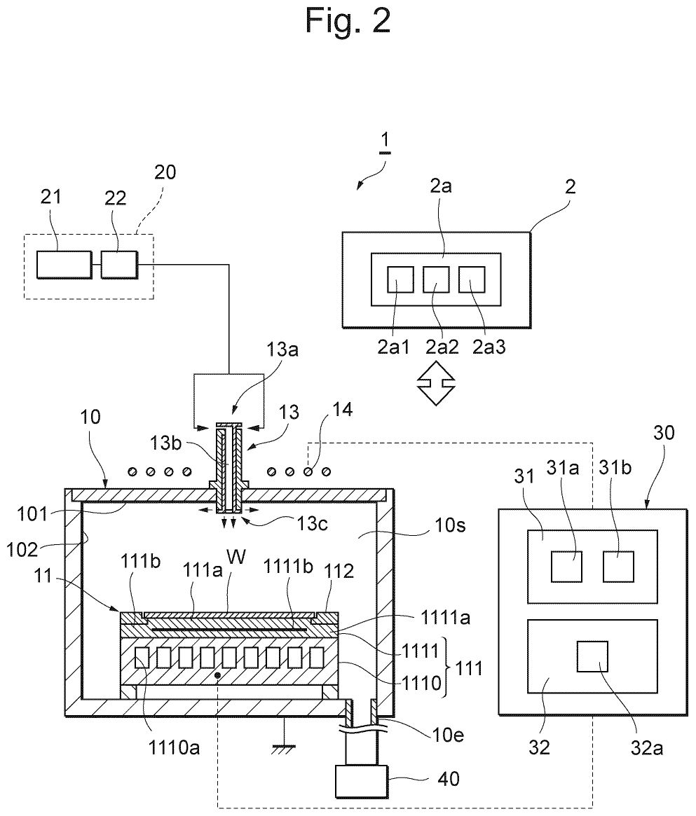

Next, a configuration example of the inductively coupled plasma processing apparatus as an example of the plasma processing apparatus 1 will be described. FIG. 2 is a diagram for describing the configuration example of the inductively coupled plasma processing apparatus.

The inductively coupled plasma processing apparatus 1 includes the controller 2, the plasma processing chamber 10, the gas supply 20, a power supply 30, and the exhaust system 40. The plasma processing chamber 10 includes a dielectric window 101. In addition, the plasma processing apparatus 1 includes a substrate support 11, a gas introducer, and an antenna 14. The substrate support 11 is disposed in the plasma processing chamber 10 (hereinafter, also referred to as a “chamber 10”). The antenna 14 is disposed on or above the plasma processing chamber 10 (that is, on or above the dielectric window 101). The plasma processing chamber 10 has a plasma processing space 10s defined by the dielectric window 101, a side wall 102 of the plasma processing chamber 10, and the substrate support 11. The plasma processing chamber 10 is grounded.

The substrate support 11 includes a main body 111 and a ring assembly 112. The main body 111 has a center region 111a for supporting the substrate W and an annular region 111b for supporting the ring assembly 112. A wafer is an example of the substrate W. The annular region 111b of the main body 111 surrounds the center region 111a of the main body 111 in plan view. The substrate W is disposed on the center region 111a of the main body 111, and the ring assembly 112 is disposed on the annular region 111b of the main body 111 to surround the substrate W on the center region 111a of the main body 111. Therefore, the center region 111a is also referred to as a substrate support surface for supporting the substrate W, and the annular region 111b is also referred to as a ring support surface for supporting the ring assembly 112.

In an embodiment, the main body 111 includes a base 1110 and an electrostatic chuck 1111. The base 1110 includes a conductive member. The conductive member of the base 1110 may function as a bias electrode. The electrostatic chuck 1111 is disposed on the base 1110. The electrostatic chuck 1111 includes a ceramic member 1111a and an electrostatic electrode 1111b disposed in the ceramic member 1111a. The ceramic member 1111a has the center region 111a. In an embodiment, the ceramic member 1111a also has the annular region 111b. Another member that surrounds the electrostatic chuck 1111 may have the annular region 111b, such as an annular electrostatic chuck or an annular insulating member. In this case, the ring assembly 112 may be disposed on the annular electrostatic chuck or the annular insulating member, or may be disposed on both the electrostatic chuck 1111 and the annular insulating member. Further, at least one RF/DC electrode coupled to a RF power supply 31 and/or a DC power supply 32, which will be described later, may be disposed in the ceramic member 1111a. In this case, at least one RF/DC electrode functions as the bias electrode. The conductive member of the base 1110 and at least one RF/DC electrode may function as a plurality of bias electrodes. Further, the electrostatic electrode 1111b may function as the bias electrode. Therefore, the substrate support 11 includes at least one bias electrode.

The ring assembly 112 includes one or a plurality of annular members. In an embodiment, one or the plurality of annular members includes one or a plurality of edge rings and at least one cover ring. The edge ring is formed of a conductive material or an insulating material, and the cover ring is formed of an insulating material.

In addition, the substrate support 11 may include a temperature-controlled module configured to adjust at least one of the electrostatic chuck 1111, the ring assembly 112, and the substrate to a target temperature. The temperature-controlled module may include a heater, a heat transfer medium, a flow passage 1110a, or a combination thereof. A heat transfer fluid such as brine or a gas flows in the flow passage 1110a. In an embodiment, the flow passage 1110a is formed in the base 1110, and one or a plurality of heaters is disposed in the ceramic member 1111a of the electrostatic chuck 1111. Further, the substrate support 11 may include a heat transfer gas supply configured to supply the heat transfer gas to a gap between a back surface of the substrate W and the center region 111a.

The gas introducer is configured to introduce at least one processing gas from the gas supply 20 into the plasma processing space 10s. In an embodiment, the gas introducer includes a center gas injector (CGI) 13. The center gas injector 13 is disposed above the substrate support 11 and is attached to a center opening portion formed in the dielectric window 101. The center gas injector 13 has at least one gas supply port 13a, at least one gas passage 13b, and at least one gas introduction port 13c. The processing gas supplied to the gas supply port 13a passes through the gas passage 13b and is introduced into the plasma processing space 10s from the gas introduction port 13c. In addition, the gas introducer may include one or a plurality of side gas injectors (SGI) attached to one or a plurality of opening portions formed in the side wall 102 in addition to or instead of the center gas injector 13.

The gas supply 20 may include at least one gas source 21 and at least one flow rate controller 22. In an embodiment, the gas supply 20 is configured to supply at least one processing gas from the gas sources 21 each corresponding thereto to the gas introducer via the flow rate controllers 22 each corresponding thereto. Each flow rate controller 22 may include, for example, a mass flow controller or a pressure-controlled flow rate controller. Further, the gas supply 20 may include at least one flow rate modulation device that modulates or pulses a flow rate of at least one processing gas.

The power supply 30 includes the RF power supply 31 coupled to the plasma processing chamber 10 via at least one impedance matching circuit. The RF power supply 31 is configured to supply at least one RF signal (RF power) to at least one bias electrode and the antenna 14. As a result, plasma is formed from at least one processing gas supplied to the plasma processing space 10s. Therefore, the RF power supply 31 may function as at least a part of the plasma generator 12. Further, by supplying the bias RF signal to at least one bias electrode, the bias potential is generated on the substrate W, and ions in the formed plasma are able to be drawn into the substrate W.

In an embodiment, the RF power supply 31 includes a first RF generator 31a and a second RF generator 31b. The first RF generator 31a is coupled to the antenna 14 via at least one impedance matching circuit and is configured to generate the source RF signal (source RF power) for plasma formation. In an embodiment, the source RF signal has a frequency in the range of 10 MHz to 150 MHz. In an embodiment, the first RF generator 31a may be configured to generate a plurality of source RF signals having different frequencies. The generated one or plurality of source RF signals is supplied to the antenna 14.

The second RF generator 31b is coupled to at least one bias electrode via at least one impedance matching circuit and is configured to generate the bias RF signal (bias RF power). The frequency of the bias RF signal may be the same as or different from the frequency of the source RF signal. In an embodiment, the bias RF signal has a frequency lower than the frequency of the source RF signal. In an embodiment, the bias RF signal has a frequency in the range of 100 kHz to 60 MHz. In an embodiment, the second RF generator 31b may be configured to generate a plurality of bias RF signals having different frequencies. The generated one or plurality of bias RF signals is supplied to at least one bias electrode. In addition, in various embodiments, at least one of the source RF signal and the bias RF signal may be pulsed.

In addition, the power supply 30 may include the DC power supply 32 coupled to the plasma processing chamber 10. The DC power supply 32 includes a bias DC generator 32a. In an embodiment, the bias DC generator 32a is connected to at least one bias electrode and is configured to generate the bias DC signal. The generated bias DC signal is applied to at least one bias electrode.

In various embodiments, the bias DC signal may be pulsed. In this case, a sequence of voltage pulses is applied to at least one bias electrode. The voltage pulse may have a pulse waveform having a rectangular shape, a trapezoidal shape, a triangular shape, or a combination thereof. In an embodiment, the waveform generator for generating the sequence of voltage pulses from the DC signal is connected between the bias DC generator 32a and at least one bias electrode. Therefore, the bias DC generator 32a and the waveform generator configure the voltage pulse generator. The voltage pulse may have a positive polarity or a negative polarity. In addition, the sequence of voltage pulses may include one or a plurality of positively-polarized voltage pulses and one or a plurality of negatively-polarized voltage pulses in one cycle. The bias DC generator 32a may be provided in addition to the RF power supply 31 or may be provided in place of the second RF generator 31b.

The antenna 14 includes one or a plurality of coils. In an embodiment, the antenna 14 may include an outer coil and an inner coil disposed coaxially. In this case, the RF power supply 31 may be connected to both the outer coil and the inner coil, or may be connected to any one of the outer coil and the inner coil. In the former case, the same RF generator may be connected to both the outer coil and the inner coil, or separate RF generators may be connected to the outer coil and the inner coil separately.

The exhaust system 40 may be connected to, for example, a gas exhaust port 10e provided at a bottom portion of the plasma processing chamber 10. The exhaust system 40 may include a pressure regulating valve and a vacuum pump. The pressure in the plasma processing space 10s is adjusted by the pressure regulating valve. The vacuum pump may include a turbo molecular pump, a dry pump, or a combination thereof.

### <Opening Blockage of Mask>

In etching using plasma, it is known that an opening of a mask is narrowed or blocked (hereinafter, also referred to as “opening blockage”). When the opening blockage occurs, the opening blockage is able to cause etching to stop or shape abnormalities such as bowing. The opening blockage may occur due to a deposition material in the plasma adhering to an opening side wall, a mask material sputtered by the ions in the plasma re-adhering to the opening side wall, or the like.

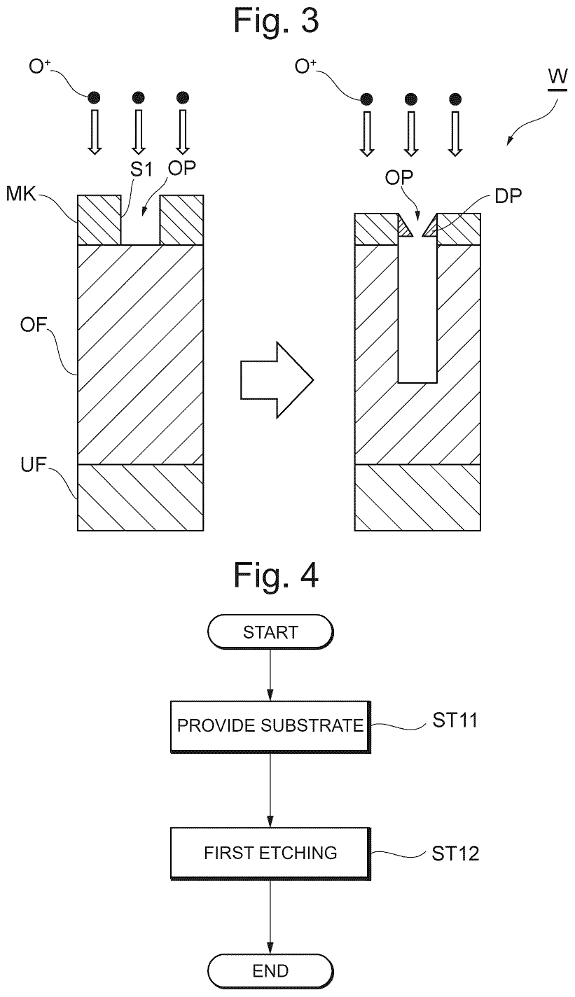

FIG. 3 is a diagram for describing an example of opening blockage. The example illustrated in FIG. 3 is an example of case where the substrate W is etched using plasma formed from a processing gas consisting of O₂ gas and COS gas. The substrate W has an underlying film UF, a carbon-containing film OF, and a mask MK having an opening OP. In this example, the carbon-containing film OF is an amorphous carbon film, and the mask MK is a silicon oxynitride (SiON) film. As illustrated from a left diagram to a right diagram of FIG. 3, as the etching progresses, a deposit DP adheres to a side wall S1 of the mask MK, and the opening OP is blocked. The deposit DP may include, for example, a mask material (in this example, silicon) sputtered by the ions in the plasma.

An etching method (hereinafter, referred to as “the present method”) according to one exemplary embodiment of the present disclosure may suppress such opening blockage. Hereinafter, an example of the present method will be described with reference to the drawings.

### First Embodiment

FIG. 4 is a flowchart related to a first embodiment of the present method. As illustrated in FIG. 4, the present method may include step ST11 of providing a substrate and step ST12 of executing first etching. The processing in each step may be executed by the above-described plasma processing apparatus 1. In the following description, a case where the controller 2 controls each unit of the inductively coupled plasma processing apparatus 1 (see FIG. 2) to execute the present method on the substrate W will be described as an example.

### (Step ST11: Provision of Substrate)

First, in step ST11, the substrate W is provided in a plasma processing space 10s of the plasma processing apparatus 1. The substrate W is carried into the chamber 10 by a transport arm and is placed on the center region 111a of the substrate support 11. The substrate W is suction-held on the substrate support 11 by the electrostatic chuck 1111.

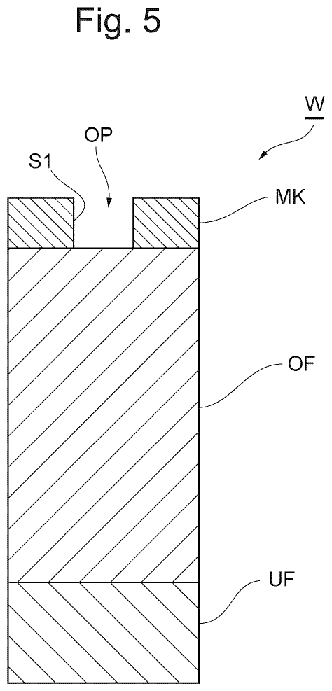

FIG. 5 is a diagram illustrating an example of a cross-sectional structure of the substrate W provided in step ST11. The substrate W has the carbon-containing film OF and the mask MK. The substrate W may further include the underlying film UF. The substrate W may be used for manufacturing a semiconductor device. The semiconductor device includes, for example, a semiconductor memory device such as DRAM or 3D-NAND flash memory.

In an embodiment, the underlying film UF is a silicon wafer, an organic film, a dielectric film, a metal film, a semiconductor film, or a film stack thereof, which is formed on the silicon wafer. In an embodiment, the underlying film UF may include a silicon-containing film. The silicon-containing film may be, for example, a silicon oxide film, a silicon nitride film, a silicon carbonitride film, a polycrystalline silicon film, or a film stack including two or more of these films. For example, the silicon-containing film may be configured by alternately stacking the silicon oxide film and the silicon nitride film. For example, the silicon-containing film SF may be configured by alternately stacking the silicon oxide film and the polycrystalline silicon film. The silicon-containing film SF may be, for example, a film stack including the silicon nitride film, the silicon oxide film, and the polycrystalline silicon film.

The carbon-containing film OF is an organic film. The carbon-containing film OF is an etching target film to be etched in the present method. In an embodiment, the carbon-containing film OF is an amorphous carbon film, a spin-on carbon (SOC) film, or a photoresist film. The amorphous carbon (ACL) film may be doped with an element such as boron, and may be, for example, a boron-containing amorphous carbon film (B-doped ACL), an arsenic-containing amorphous carbon film (As-doped ACL), a tungsten-containing amorphous carbon film (W-doped ACL), or a xenon-containing amorphous carbon film (Xe-doped ACL).

The carbon-containing film OF may be configured of one film, or may be configured by stacking a plurality of films.

In an embodiment, the mask MK is formed of a material having an etching rate with respect to the plasma formed in step ST12 lower than that of the carbon-containing film OF. In an embodiment, the mask MK includes a silicon-containing film or a metal-containing film. The silicon-containing film may be, for example, a silicon oxide film, a silicon nitride film, a silicon carbonitride film, a polycrystalline silicon film, or a film stack including two or more of these films. For example, the silicon-containing film may be configured by alternately stacking the silicon oxide film and the silicon nitride film. For example, the silicon-containing film SF may be configured by alternately stacking the silicon oxide film and the polycrystalline silicon film. The silicon-containing film may be, for example, a film stack including the silicon nitride film, the silicon oxide film, and the polycrystalline silicon film. The metal-containing film may be, for example, a film containing at least one selected from the group consisting of tungsten, titanium, and molybdenum.

In an embodiment, the mask MK may have a pattern that is transferred to the carbon-containing film OF by etching. The mask MK may be a single-layer mask consisting of one layer, or may be a multilayer mask consisting of two or more layers. As illustrated in FIG. 5, the mask MK has a side wall S1 that defines at least one opening OP on the carbon-containing film OF. The opening OP is a space on the carbon-containing film OF and is surrounded by the side wall S1 of the mask MK. That is, the upper surface of the carbon-containing film OF has a region covered with the mask MK and a region exposed at a bottom portion of the opening OP.

The opening OP may have any shape in plan view of the substrate W, that is, when the substrate W is viewed in a direction from the top to the bottom of FIG. 5. The shape may be, for example, a circle, an ellipse, a rectangle, a line, or a shape in which one or more of these are combined. The mask MK may have a plurality of side walls, and the plurality of side walls may define a plurality of openings OP. The plurality of openings OP may each have a linear shape and may be arranged at regular intervals to form a line-and-space pattern (trench). Further, the plurality of openings OP may each have a hole shape and may form an array pattern.

Each of the films (the underlying film UF, the carbon-containing film OF, and the mask MK) constituting the substrate W may be formed by a CVD method, an ALD method, a PVD method, a spin coating method, or the like. The opening OP of the mask MK may be formed by etching the mask MK, or may be formed by lithography. Each of the films may be a flat film or a film having irregularities. The substrate W may further have another film under the underlying film UF. In this case, a concave portion having a shape corresponding to the opening OP may be formed in the carbon-containing film OF and the underlying film UF, and the other film may be used as a mask for etching.

At least a part of the process of forming each film of the substrate W may be performed in the space of the chamber 10. In an example, the step of etching the mask MK to form the opening OP may be executed in the chamber 10. That is, the etching of the carbon-containing film OF in the opening OP and in step ST12 described later may be continuously executed in the same chamber. Further, after the entire each film of the substrate W is formed by an external device or a chamber of the plasma processing apparatus 1, the substrate W is carried into the plasma processing space 10s of the plasma processing apparatus 1 and is disposed on the center region 111a of the substrate support 11, and thereby the substrate W may be provided.

In an embodiment, after the substrate W is provided in the center region 111a of the substrate support 11, the substrate support 11 is controlled to a first temperature by the temperature-controlled module. In an example, controlling the temperature of the substrate support 11 to the first temperature includes setting the temperature of the heat transfer fluid flowing through the flow passage 1110a and the heater temperature to the first temperature or a temperature different from the first temperature. Timing at which the heat transfer fluid starts to flow through the flow passage 1110a may be before or after the substrate W is placed on the substrate support 11, or may be at the same time. In addition, the temperature of the substrate support 11 may be controlled to the first temperature before step ST11. That is, the substrate W may be provided on the substrate support 11 after the temperature of the substrate support 11 is controlled to the first temperature.

The first temperature may be appropriately set depending on the type of the carbon-containing film OF and the type of the processing gas (first processing gas) used in step ST12. In an embodiment, the first temperature is equal to or lower than 0° C. and equal to or higher than −70° C. In an example, the first temperature is −10° C. or lower, −20° C. or lower, −30° C. or lower, −40° C. or lower, −50° C. or lower, or −60° C. or lower.

In an embodiment, instead of controlling the substrate support 11 to the first temperature, the substrate W may be controlled to the first temperature. Controlling the temperature of the substrate W to the first temperature includes setting the temperature of the heat transfer fluid flowing through the substrate support 11 and the flow passage 1110a and/or the heater temperature to the first temperature or to a temperature different from the first temperature.

### (Step ST12: First Etching)

In step ST12, the first etching is executed. By the first etching, the carbon-containing film OF of the substrate W is etched to form the concave portion RC.

First, the first processing gas is supplied from the gas supply 20 into the plasma processing space 10s. In an embodiment, the first processing gas includes a phosphorus halide gas, an oxygen-containing gas, and a sulfur-containing gas. In an embodiment, the first processing gas includes a phosphorus halide gas, and an oxygen- and sulfur-containing gas.

In an embodiment, the oxygen-containing gas includes at least one gas selected from the group consisting of an O₂ gas, a CO gas, and a CO₂ gas.

In an embodiment, the phosphorus halide gas may be, for example, a fluorine halide gas containing fluorine as a halogen element, such as PF₃ gas or PF₅ gas. In an embodiment, the phosphorus halide gas may be a chlorine halide gas containing chlorine as a halogen element, such as PCl₃ gas or PCl₃ gas. In an embodiment, the phosphorus halide gas may be a gas containing bromine or iodine as a halogen element, such as a PBr₃ gas, a PBr₃ gas, or a Pls gas. In an embodiment, the phosphorus halide gas may be a gas containing two or more halogen elements, such as a PClF₂ gas, a PCl₂F gas, or a PCl₂F₃ gas. In an embodiment, the phosphorus halide gas may be an oxyfluorine halide gas or an oxychlorine halide gas. For example, the phosphorus halide gas may be a POF₃ gas, a POCl₃ gas, a POF₂Cl₂ gas, a POFCl₂ gas, or a POF₂Cl gas.

In an embodiment, the flow rate of the phosphorus halide gas is 0.1 vol % or more and 5 vol % or less of the total flow rate of the first processing gas (in a case where the first processing gas includes an inert gas, the inert gas is excluded)

In an embodiment, the sulfur-containing gas may be SF₆ gas.

In an embodiment, the oxygen- and sulfur-containing gas may be a COS gas or an SO₂ gas.

In an embodiment, the first processing gas may further include an inert gas. In an example, the inert gas may be a noble gas such as Ar gas, He gas, and Kr gas, or nitrogen gas.

Next, the source RF signal is supplied to the antenna 14. As a result, a RF electric field is generated in the plasma processing space 10s, plasma is generated from the first processing gas, and the carbon-containing film OF is etched. A bias signal may be supplied to the lower electrode of the substrate support 11. In this case, a bias potential is generated between the plasma and the substrate W, and active species such as ions and radicals in the plasma are drawn to the substrate W, and etching of the carbon-containing film OF may be promoted. The bias signal may be the bias RF signal supplied from the second RF generator 31b. In addition, the bias signal may be the bias DC signal supplied from the DC generator 32a.

In an embodiment, both the source RF signal and the bias signal may be continuous waves or pulse waves, or one may be the continuous wave and the other may be the pulse wave. In a case where both of the source RF signal and the bias signal are the pulse waves, cycles of both pulse waves may or may not be synchronized. A duty ratio of the pulse wave of the source RF signal and/or the bias signal may be appropriately set, and may be, for example, 1 to 80% and 5 to 50%. In addition, in a case where the bias DC signal is used as the bias signal, the pulse wave may have a rectangular shape, a trapezoidal shape, a triangular shape, or a waveform of a combination thereof. The polarity of the bias DC signal may be negative or positive as long as the potential of the substrate W is set to give a potential difference between plasma and the substrate to draw ions.

In an embodiment, in step ST12, the supply and the stop of at least one of the source RF signal and the bias signal may be alternately repeated. For example, while the source RF signal is continuously supplied, the supply and stop of the bias signal may be alternately repeated. Further, for example, while the supply and stop of the source RF signal are alternately repeated, the bias signal may be continuously supplied. Further, for example, the supply and stop of both the source RF signal and the bias signal may be alternately repeated.

In an embodiment, during the processing in step ST12, the temperature of the substrate support 11 may be controlled to the first temperature set in step ST11. In an embodiment, the temperature of the substrate W may be controlled to the first temperature instead of the temperature of the substrate support 11.

By the processing in step ST12, in the carbon-containing film OF, a portion (a portion exposed in the opening OP) that is not covered by the mask MK is etched to form a concave portion RC.

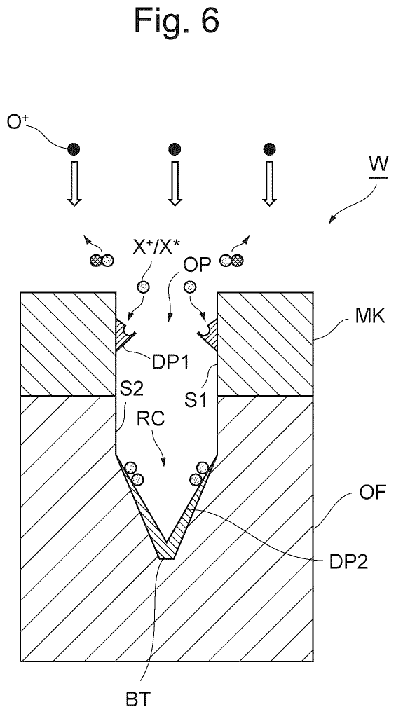

FIG. 6 is a diagram for describing an example of a phenomenon occurring in step ST12. FIG. 6 is a diagram schematically illustrating a cross-sectional structure of the substrate W in the vicinity of the mask MK in step ST12. As illustrated in FIG. 6, in step ST12, a portion of the carbon-containing film OF, which is exposed at the opening OP, is etched in a depth direction (a direction from the top to the bottom in FIG. 6) by the active species (for example, oxygen ions O⁺) in the plasma, and the concave portion RC is formed. The concave portion RC is a space defined by the side wall S2 and the bottom portion BT of the carbon-containing film OF.

As illustrated in FIG. 6, in an embodiment, a first deposition film DP1 is formed on the side wall S1 of the mask MK during the execution of step ST12. The first deposition film DP1 may be formed, for example, by re-adhering a mask material sputtered by ions (for example, oxygen ions O⁺ or the like) in the plasma to the side wall S1. For example, in a case where the mask MK includes a silicon-containing film, the deposition film DP may include silicon. During the execution of step ST, as schematically illustrated in FIG. 6, the first deposition film DP1 may be volatilized and removed by being coupled to a halogen active species (a halogen ion X⁺ or a halogen radical X*) in the plasma deviated from the phosphorus halide gas.

As illustrated in FIG. 6, in an embodiment, during the execution of step ST12, a second deposition film DP2 is formed on at least a part of the side wall S2 and the bottom portion BT of the carbon-containing film OF. The second deposition film DP2 may be, for example, a non-volatile byproduct generated by etching. In an embodiment, the second deposition film DP2 contains a phosphorus oxide compound or an organic phosphorus compound. In an embodiment, the second deposition film DP2 is formed from the bottom portion BT in a bottom-up manner during the execution of step ST12. That is, as schematically illustrated in FIG. 6, the second deposition film DP2 may be formed on the bottom portion BT and the side wall S2 in the vicinity of the bottom portion BT. In an embodiment, the second deposition film DP2 has a higher etching resistance against the halogen active species in the plasma than the carbon-containing film OF. That is, the second deposition film DP2 may function as a protective film against the halogen active species in the plasma on the side wall S2 or the bottom portion BT on which the second deposition film DP2 is formed.

According to the first embodiment of the present method, in step ST12, the first deposition film DP1 formed in the opening OP may be removed by the halogen active species in the plasma. Therefore, the blockage of the opening OP with the progress of the etching may be suppressed. In addition, since the second deposition film DP2 formed during the execution of step ST12 functions as the protective film, the side wall S2 on which the second deposition film DP2 is formed may be suppressed from being etched in the horizontal direction (the left-right direction in FIG. 6).

### Second Embodiment

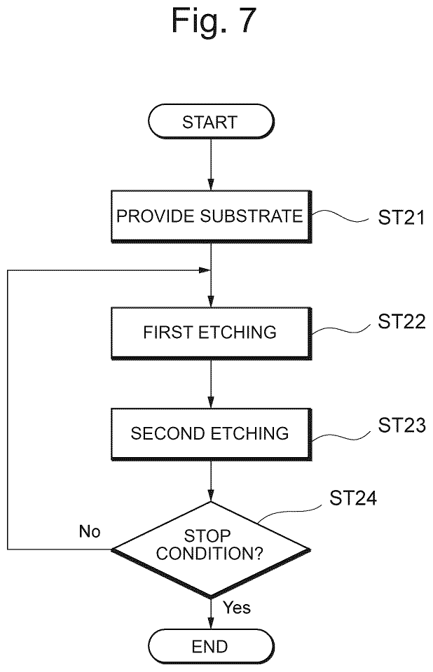

FIG. 7 is a flowchart related to a second embodiment of the present method. As illustrated in FIG. 7, the present method may include step ST21 of providing a substrate, step ST22 of executing a first etching, step ST23 of executing a second etching, and step ST24 of determining whether an etching stop condition is satisfied. That is, in the present method, a cycle including the first etching (step ST22) and the second etching (step ST23) may be repeated until it is determined that the stop condition is satisfied in step ST24.

### (Step ST21 and Step ST22)

Each of step ST21 and step ST22 may be executed in the same manner as step ST11 and step ST12 of the first embodiment described above, and the description thereof will be omitted.

### (Step ST23: Second Etching)

In step ST23, the second etching is executed. By the second etching, the concave portion RC of the carbon-containing film OF of the substrate W is further etched.

First, the second processing gas is supplied from the gas supply 20 into the plasma processing space 10s. The second processing gas is a gas different from the first processing gas. The second processing gas includes an oxygen-containing gas and a sulfur-containing gas, or includes an oxygen- and sulfur-containing gas. The second processing gas does not include the phosphorus halide gas or includes the phosphorus halide gas at a flow rate lower than the flow rate of the phosphorus halide gas included in the first processing gas.

In an embodiment, the oxygen-containing gas includes at least one gas selected from the group consisting of an O₂ gas, a CO gas, and a CO₂ gas. In a case where the oxygen-containing gas is included in both the first processing gas and the second processing gas, the oxygen-containing gas included in the second processing gas may be the same as or different from the first processing gas.

In an embodiment, the phosphorus halide gas may be, for example, a fluorine halide gas containing fluorine as a halogen element, such as PF₃ gas or PF₅ gas. In an embodiment, the phosphorus halide gas may be a chlorine halide gas containing chlorine as a halogen element, such as PCl₃ gas or PCl₅ gas. In an embodiment, the phosphorus halide gas may be a gas containing bromine or iodine as a halogen element, such as a PBr₃ gas, a PBr₅ gas, or a Pls gas. In an embodiment, the phosphorus halide gas may be a gas containing two or more halogen elements, such as a PClF₂ gas, a PCl₂F gas, or a PCl₂F₃ gas. In an embodiment, the phosphorus halide gas may be the oxyfluorine halide gas or the oxychlorine halide gas. For example, the phosphorus halide gas may be a POF₃ gas, a POCl₃ gas, a POF₂Cl₂ gas, a POFCl₂ gas, or a POF₂Cl gas. In a case where the second processing gas includes the phosphorus halide gas, the phosphorus halide gas may be the same type of gas as the first processing gas or may be different from the first processing gas.

In an embodiment, the sulfur-containing gas may be SF₆ gas.

In an embodiment, the gas may be the oxygen- and sulfur-containing gas, the COS gas, or the SO₂ gas. In a case where both the first processing gas and the second processing gas include the oxygen- and sulfur-containing gas, the oxygen- and sulfur-containing gas included in the second processing gas may be the same type of gas as the first processing gas or a type different from the first processing gas.

In an embodiment, the second processing gas may further include an inert gas. In an example, the inert gas may be a noble gas such as Ar gas, He gas, and Kr gas, or nitrogen gas.

Next, the source RF signal is supplied to the antenna 14. As a result, a RF electric field is generated in the plasma processing space 10s, plasma is formed from the second processing gas, and the carbon-containing film OF is etched. A bias signal may be supplied to the lower electrode of the substrate support 11. In this case, a bias potential is generated between the plasma and the substrate W, and active species such as ions and radicals in the plasma are drawn to the substrate W, and etching of the carbon-containing film OF may be promoted. The configuration and supply form of the source signal or the bias signal may be the same as or different from those in step ST22 (step ST12).

In an embodiment, during the processing in step ST23, the temperature of the substrate support 11 may be controlled to the same temperature (that is, the first temperature) as in step ST22. In an embodiment, the temperature of the substrate W may be controlled instead of the temperature of the substrate support 11.

### (Step ST24: Determination Stop)

In step ST24, it is determined whether the stop condition is satisfied. The stop condition may be, for example, whether the number of repetitions of the cycle in which step ST22 and step ST23 are performed as one cycle reaches a given number of times. The stop condition may be, for example, whether an etching time reaches a given time. The stop condition may be, for example, whether the depth of the concave portion RC formed by etching reaches a given depth. When it is determined that the stop condition is not satisfied in step ST24, the cycle including step ST22 and step ST23 is repeated. When it is determined that the stop condition is satisfied in step ST24, the etching is stopped, and the present method is ended.

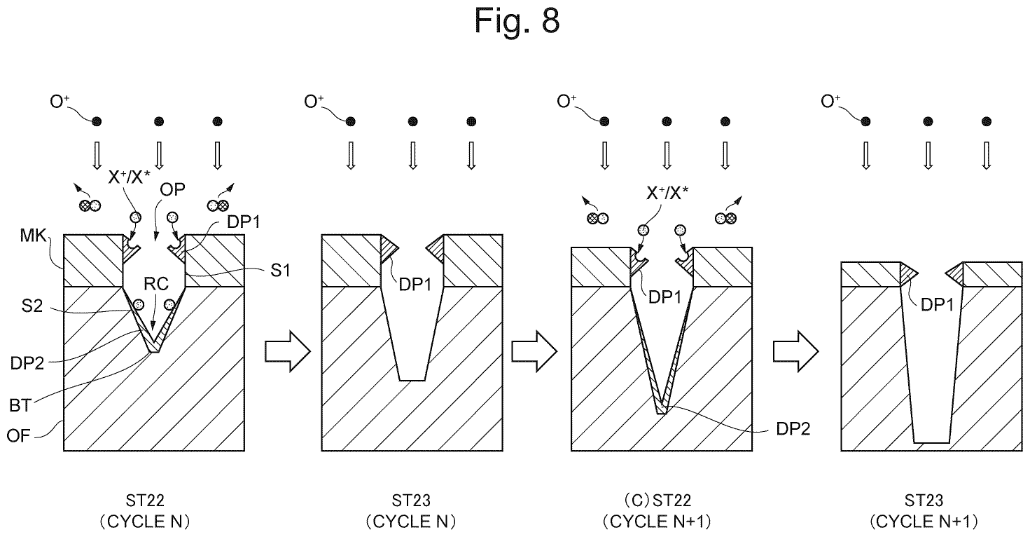

FIG. 8 is a diagram for describing an example of a phenomenon that occurs in a repeated cycle of step ST22 and step ST23.

As illustrated in FIG. 8, in step ST22 (first etching) of a cycle N (N is an integer of 1 or more), the same phenomenon as described in FIG. 6 may occur. That is, in this step, the concave portion RC is etched in the depth direction by the active species (for example, oxygen ions O⁺) in the plasma. In addition, the first deposition film DP1 formed on the side wall S1 of the mask MK may be removed by the halogen active species (halogen ion X⁺ or halogen radical X*) in the plasma. Furthermore, the second deposition film DP2 that functions as the protective film against the halogen active species in the plasma may be formed on at least a part of the side wall S2 and the bottom portion BT of the carbon-containing film OF.

In step ST23 (second etching) of the cycle N, the concave portion RC is further etched in the depth direction by the active species (for example, oxygen ions O⁺) in the plasma. Here, the second processing gas does not include the phosphorus halide gas, or includes the phosphorus halide gas at a flow rate lower than that of the first processing gas. Therefore, in step ST23, the halogen active species in the plasma is reduced as compared with step ST22, and a phosphorus active species is also reduced. As a result, the formation of the first deposition film DP1 is predominant on the side wall S1 of the mask MK. In addition, the second deposition film DP2 is reduced or removed on the side wall S2 and the bottom portion BT of the carbon-containing film OF.

In step ST22 of the cycle N+1, the concave portion RC is further etched in the depth direction by active species (for example, oxygen ions O⁺) in the plasma. Then, the first deposition film DP1 formed on the side wall S1 of the mask MK is able to be removed in the same manner as in step ST22 of the cycle N. In addition, the second deposition film DP2 is able to be reformed on at least a part of the side wall S2 and the bottom portion BT of the carbon-containing film OF.

In step ST23 of the cycle N+1, the concave portion RC is further etched in the depth direction by the active species (for example, oxygen ions O⁺) in the plasma. Then, the formation of the first deposition film DP1 is predominant on the side wall S1 of the mask MK in the same manner as in step ST23 of the cycle N. In addition, in the side wall S2 and the bottom portion BT of the carbon-containing film OF, the second deposition film DP2 is reduced or removed.

Incidentally, when in a case where the halogen active species in the plasma are excessive, a portion of the side wall S2 of the carbon-containing film OF, which is not covered with the second deposition film DP2, may be etched in the horizontal direction, which may cause an increase in the opening width (CD) of the concave portion RC or the occurrence of bowing. In addition, the upper portion of the mask MK may be excessively etched, which may cause deterioration of the selectivity.

In this regard, according to the second embodiment of the present method, a cycle including the first etching (step ST22) and the second etching (step ST23) is alternately repeated. That is, as the processing gas, step ST22 including phosphorus halide and step ST23 including no phosphorus halide gas or including phosphorus halide in a smaller flow rate than that in step ST22 are repeated. As a result, the amount of the halogen active species deviating in the plasma is able to be adjusted. According to the second embodiment of the present method, it is possible to suppress the occurrence of the above-described problem due to the excess of the halogen active species in the plasma. That is, it is possible to suppress a shape abnormality (CD enlargement and bowing) due to etching or a decrease in the etching selectivity.

The execution time of the etching in step ST22 and the step 23 may be appropriately set. In an embodiment, the execution time of step ST22 and step ST23 may be set according to the flow rate of the phosphorus halide gas included in the first processing gas and/or the second processing gas, the type of the mask MK or the carbon-containing film OF, the depth of the concave portion RC, the aspect ratio, and the like. In an embodiment, a ratio of the execution time of the etching in the step ST23 to the execution time of the etching in step ST22 may be 0.8 or more and 1.2 or less. In an embodiment, the ratio may be 0.9 or more and 1.1 or less. In an embodiment, the ratio may be set according to the number of cycles. For example, when in a case where the number of cycles exceeds a given number of times or for each given number of cycles, the ratio may be increased. As a result, the etching time in step ST23 may be longer than that in step ST22 as the depth of the concave portion RC formed in the carbon-containing film OF increases. In an embodiment, the ratio may be set according to the depth or the aspect ratio of the concave portion RC, instead of the number of cycles. For example, when in a case where the depth or the aspect ratio of the concave portion RC exceeds a given value or increases by a given value, the ratio may be increased.

In an embodiment, during the processing in step ST23, the temperature of the substrate support 11 may be controlled to a second temperature different from the temperature in step ST22. The second temperature may be a temperature higher than the first temperature. In this case, in step ST23, the volatilization (removal) of the second deposition film DP2 is able to be promoted. In an embodiment, the first temperature and/or the second temperature may be set according to the number of cycles. For example, when in a case where the number of cycles exceeds a given number of times or for each given number of cycles, the first temperature and/or the second temperature may be increased. As a result, the temperature of the substrate support 11 may be increased as the depth of the concave portion RC formed in the carbon-containing film OF is increased. In an embodiment, the first temperature and/or the second temperature may be set according to the depth or the aspect ratio of the concave portion RC, instead of the number of cycles. For example, when in a case where the depth or the aspect ratio of the concave portion RC exceeds a given value or increases by a given value, the first temperature and/or the second temperature may be increased.

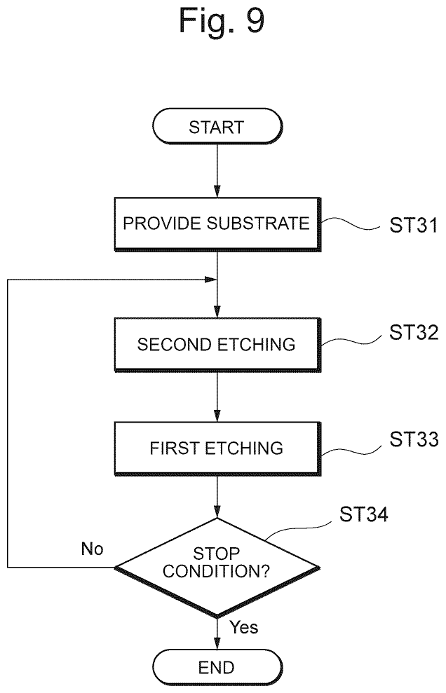

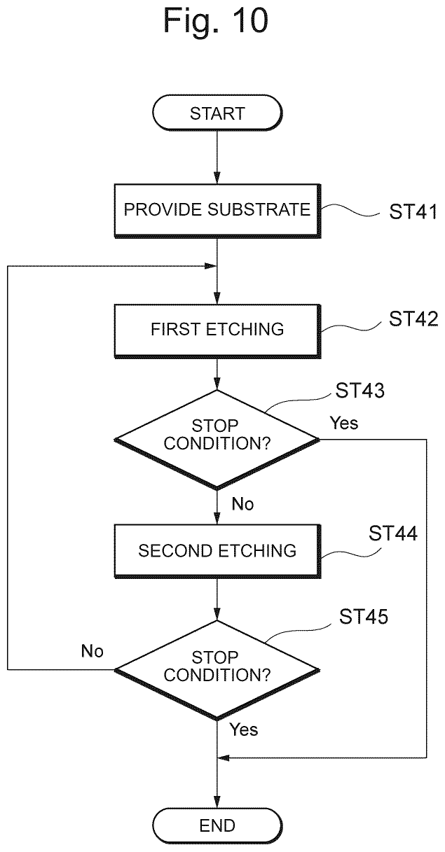

FIGS. 9 and 10 are flowcharts illustrating modification examples of the second embodiment. FIG. 7 illustrates an example in which the second etching (step ST23) is executed after the first etching (step ST22) is executed in one cycle. However, as illustrated in FIG. 9, in one cycle, the first etching (step ST33) may be executed after the second etching (step ST32) is executed. In addition, as illustrated in FIG. 10, it is also possible to determine whether the stop condition is satisfied in the middle of one cycle. That is, it may be determined whether the stop condition is satisfied even after the execution of the first etching (step ST42) (step ST43). In a case where the stop condition is satisfied, the etching may be ended without proceeding to the second etching (step ST44).

### EXAMPLES

Next, examples of the present method will be described. The present disclosure is not limited in any way by following examples.

### Example 1

In Example 1, a substrate having the same structure as the substrate W illustrated in FIG. 5 was etched along the flowchart illustrated in FIG. 4 using the plasma processing apparatus 1 illustrated in FIG. 2. The mask MK was a silicon oxynitride film, and the carbon-containing film OF was an amorphous carbon film. The opening OP of the mask MK had a hole shape, and the opening diameter was 80 nm.

In step ST12, the first processing gas contained an O₂ gas, a PF₃ gas, and a COS gas. The flow rate of the PF₃ gas was 1.3 vol % of the total flow rate of the first processing gas. In addition, in step ST12, a bias RF signal was supplied in addition to the source RF signal. In step ST12, the pressure in the chamber 10 was controlled to 30 m Torr, and the temperature of the substrate support 11 was controlled to −60° C. Step ST12 was executed for 240 seconds.

### Reference Example 1

In Reference Example 1, the substrate having the same configuration as in Example 1 was etched using the plasma processing apparatus 1. In Reference Example 1, etching was performed under the same conditions as in Example 1, except that O₂ gas and COS gas were used as the processing gas.

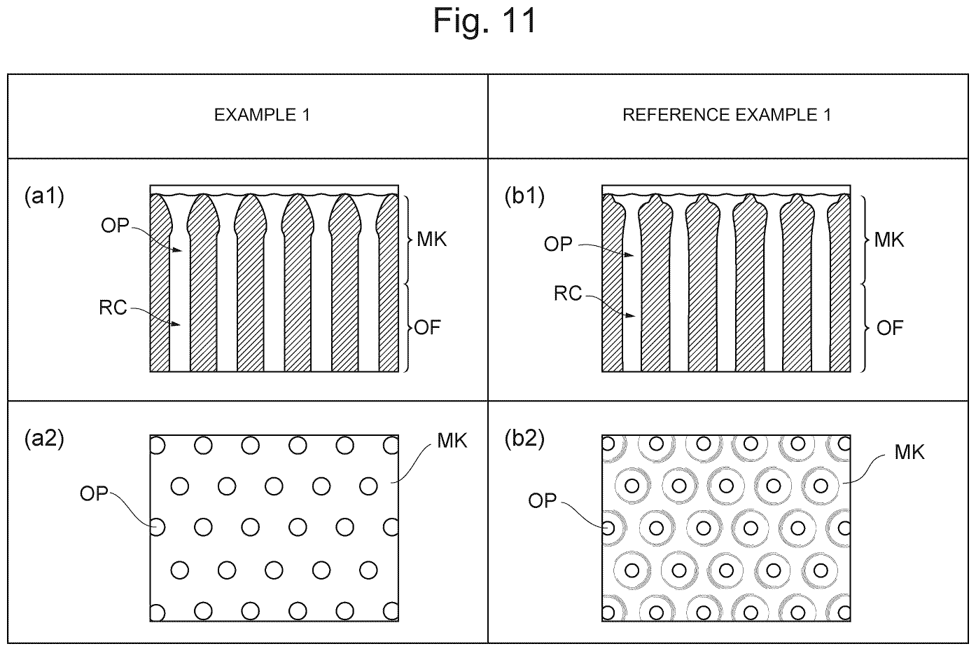

FIG. 11 is a diagram illustrating results of etching related to Example 1 and Reference Example 1. In FIGS. 11, (a1) and (b1) are diagrams illustrating cross-sectional shapes of the mask MK and the upper portion of the concave portion RC after etching related to Example 1 and Reference Example 1, respectively. Each of (a2) and (b2) is a plan view of the mask MK after etching related to Example 1 and Reference Example 1 (diagrams as viewed from above Figures (a1) and (b1)).

As illustrated in (a1) and (a2) of FIG. 11, in Example 1, the blockage of the opening OP of the mask MK was suppressed. In Example 1, the minimum opening diameter of the mask MK was 63.0 nm. On the other hand, as illustrated in (b1) and (b2) of FIG. 11, in Reference Example 1, the opening diameter was narrowed (a neck was generated) in a part of the mask MK, and the opening OP was largely blocked. In Reference Example 1, the minimum opening diameter of the mask MK was 42.8 nm.

### Example 2

In Example 2, a substrate having the same configuration as that of Example 1 was etched along the flowchart illustrated in FIG. 7 using the plasma processing apparatus 1 illustrated in FIG. 2.

In step ST22, a processing gas having the same configuration as that of Example 1 was used as the first processing gas. In step ST22, the bias RF signal was supplied in addition to the source RF signal. In addition, the pressure in the chamber 10 was controlled to 30 mTorr, and the temperature of the substrate support 11 was controlled to −60° C. In step ST23, the second processing gas included an O₂ gas and a COS gas. The other conditions were the same as the conditions in step ST22. In one cycle, the etching in step ST22 was executed for 10 seconds, and then the etching in step ST23 was executed for 10 seconds. In Example 2, the cycle was repeated 12 times, and the etching was performed for a total of 240 seconds.

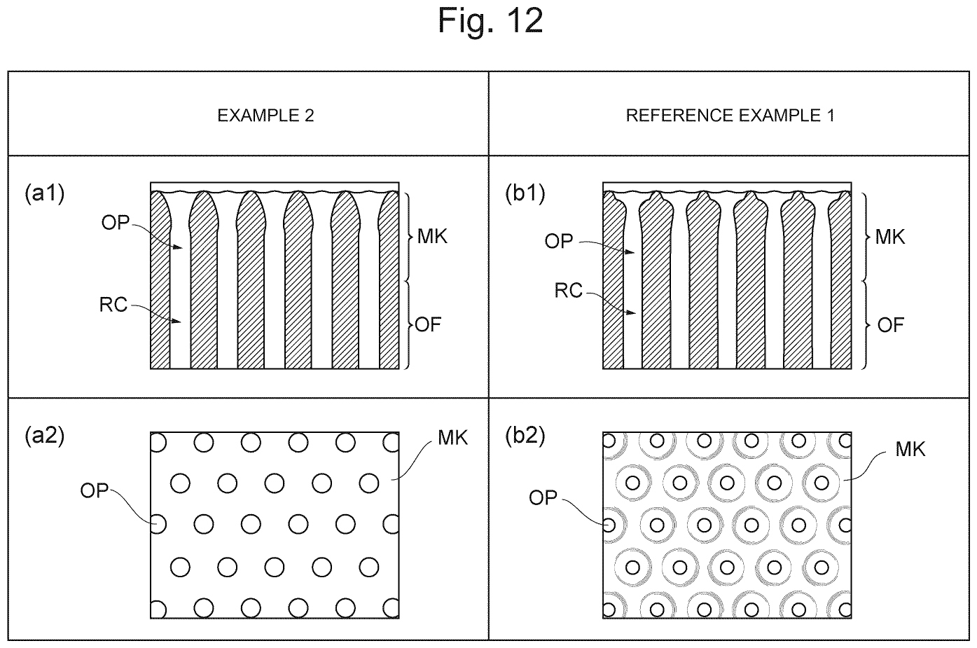

FIG. 12 is a diagram illustrating results of etching related to Example 2 and Reference Example 1. In FIG. 12, (a1) is a diagram illustrating a cross-sectional shape of the mask MK after etching and the upper portion of the concave portion RC related to Example 2. (a2) is a plan view of the mask MK after etching related to according to Example 2 (diagram as viewed from above Figure (a1)). In addition, (a2) and (b2) of FIG. 12 are reproduced again for comparison of Reference Example 1 illustrated in (a2) and (b2) of FIG. 11 with Example 2.

As illustrated in FIG. 12, in Example 2, the opening blockage of the mask MK was suppressed as compared with Reference Example 1 in the same manner as in Example 1. In Example 2, the minimum opening diameter of the mask MK was 62.6 nm.

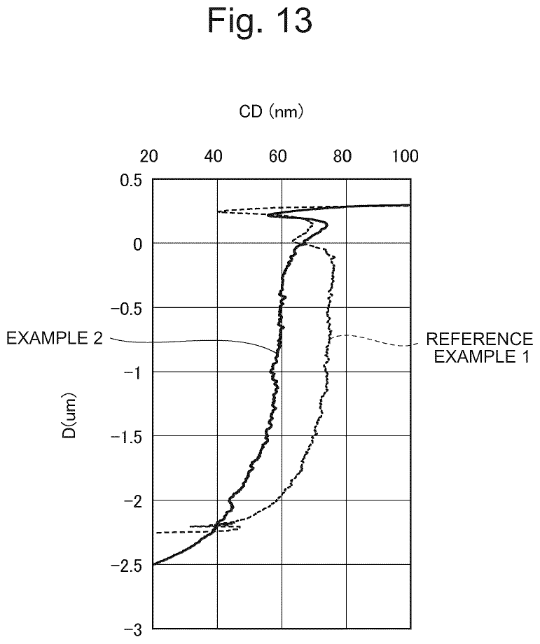

FIG. 13 is a diagram illustrating results of etching related to according to Example 2 and Reference Example 1. In FIG. 13, the vertical axis indicates a depth D [μm] of the opening OP of the mask film MK and the concave portion RC formed in the carbon-containing film OF. The vicinity of 0 μm on the vertical axis is a boundary between the mask MK and the carbon-containing film OF. In FIG. 13, the horizontal axis indicates an opening diameter CD [nm] of the opening OP of the mask film MK and the concave portion RC formed in the carbon-containing film OF.

As illustrated in FIG. 13, in Example 2, the increase in the opening diameter was suppressed over the entire depth direction of the concave portion RC, as compared with Reference Example 1. In addition, the maximum diameter of the concave portion RC of Example 2 was 67.5 nm, and the maximum diameter of the concave portion RC of Reference Example 1 was 77.4 nm. That is, in Example 2, the bowing was suppressed as compared with Reference Example 1. Furthermore, the etching selectivity (the ratio of the etching rate of the carbon-containing film OF to the etching rate of the mask MK) was 125.4 in Example 2 and 75.1 in Reference Example 1. That is, the selectivity was also improved in Example 2 as compared with Reference Example 1.

According to one exemplary embodiment of the present disclosure, it is possible to provide a technique for suppressing opening blockage of a mask.

The embodiments of the present disclosure further include the following aspects.

### (Addendum 1)

An etching method, including:
(a) providing a substrate on a substrate support in a chamber, the substrate having a carbon-containing film and a mask on the carbon-containing film; and
(b) etching the carbon-containing film using plasma formed from a first processing gas, the first processing gas containing a phosphorus halide gas, an oxygen-containing gas, and a sulfur-containing gas, or containing the phosphorus halide gas and an oxygen- and sulfur-containing gas.

### (Addendum 2)

The etching method according to Addendum 1, further including:
(c) etching the carbon-containing film using plasma formed from a second processing gas different from the first processing gas, the second processing gas containing the oxygen-containing gas and the sulfur-containing gas, or containing the oxygen- and sulfur-containing gas.

### (Addendum 3)

The etching method according to Addendum 2, in which the second processing gas does not include the phosphorus halide gas.

### (Addendum 4)

The etching method according to Addendum 2, in which the second processing gas includes the phosphorus halide gas at a flow rate lower than a flow rate of the phosphorus halide gas included in the first processing gas.

### (Addendum 5)

The etching method according to any one of Addenda 2 to 4, in which a ratio of an execution time of the etching in the (c) to an execution time of the etching in the (b) is 0.8 or more and 1.2 or less.

### (Addendum 6)

The etching method according to any one of Addenda 2 to 4, in which a cycle including the (b) and the (c) is repeated a plurality of times.

### (Addendum 7)

The etching method according to Addendum 6, in which, in at least one cycle of a second or subsequent cycles, a ratio of an execution time of the etching in the (c) to an execution time of the etching in the (b) is larger than the ratio in a first cycle.

### (Addendum 8)

The etching method according to Addendum 6 or 7, in which a temperature of the substrate support in at least one cycle of a second or subsequent cycles is set to be higher than a temperature of the substrate support in a first cycle.

### (Addendum 9)

The etching method according to any one of Addenda 1 to 8, in which the phosphorus halide gas includes at least one gas selected from the group consisting of a fluorine halide gas, a chlorine halide gas, an oxyfluorine halide gas, and an oxychlorine halide gas.

### (Addendum 10)

The etching method according to any one of Addenda 1 to 9, in which the phosphorus halide gas includes at least one gas selected from the group consisting of a PF₃ gas, a PF₅ gas, and a PCl₃ gas.

### (Addendum 11)

The etching method according to any one of Addenda 1 to 10, in which, in the first processing gas, a flow rate of the phosphorus halide gas is 5 vol % or less of a total flow rate of the first processing gas.

### (Addendum 12)

The etching method according to any one of Addenda 1 to 11, in which the oxygen-containing gas includes at least one gas selected from the group consisting of an O₂ gas, a CO gas, and a CO₂ gas.

### (Addendum 13)

The etching method according to any one of Addenda 1 to 12, in which the oxygen- and sulfur-containing gas is at least one of a COS gas and an SO₂ gas.

### (Addendum 14)

The etching method according to any one of Addenda 1 to 13, in which the sulfur-containing gas is an SF₆ gas.

### (Addendum 15)

The etching method according to any one of Addenda 1 to 14, in which the mask includes a silicon-containing film or a metal-containing film.

### (Addendum 16)

The etching method according to any one of Addenda 1 to 15, in which the carbon-containing film includes an amorphous carbon film.

### (Addendum 17)

The etching method according to any one of Addenda 1 to 16, in which, in the (b), a temperature of the substrate support is set to 0° C. or lower.

### (Addendum 18)

The etching method according to any one of Addenda 2 to 8, in which, in the (c), a temperature of the substrate support is set to 0° C. or lower.

### (Addendum 19)

A plasma processing apparatus, including:
a chamber; and
a controller, in which
the controller is configured to execute
   (a) providing a substrate on a substrate support in a chamber, the substrate having a carbon-containing film and a mask on the carbon-containing film, and
   (b) controlling of etching the carbon-containing film using plasma formed from a first processing gas, the first processing gas containing a phosphorus halide gas, an oxygen-containing gas, and a sulfur-containing gas, or containing the phosphorus halide gas and an oxygen- and sulfur-containing gas.

### (Addendum 20)

The plasma processing apparatus according to Addendum 19, in which
the controller is configured to further execute
   (c) etching the carbon-containing film using plasma formed from a second processing gas different from the first processing gas, the second processing gas containing the oxygen-containing gas and the sulfur-containing gas, or containing the oxygen- and sulfur-containing gas.

### (Addendum 21)

A device manufacturing method that is executed in a plasma processing apparatus including a chamber and a controller, the device manufacturing method, including:
(a) providing a substrate on a substrate support in a chamber, the substrate having a carbon-containing film and a mask on the carbon-containing film; and
(b) etching the carbon-containing film using plasma formed from a first processing gas, the first processing gas containing a phosphorus halide gas, an oxygen-containing gas, and a sulfur-containing gas, or containing the phosphorus halide gas and an oxygen- and sulfur-containing gas.

### (Addendum 22)

A program for causing a computer of a plasma processing apparatus including a chamber and a controller to execute
(a) providing a substrate on a substrate support in a chamber, the substrate having a carbon-containing film and a mask on the carbon-containing film, and
(b) controlling of etching the carbon-containing film using plasma formed from a first processing gas, the first processing gas containing a phosphorus halide gas, an oxygen-containing gas, and a sulfur-containing gas, or containing the phosphorus halide gas and an oxygen- and sulfur-containing gas.

### (Addendum 23)

A storage medium in which the program according to Addendum 22 is stored.

Each of the above embodiments is described for the purpose of description, and is not intended to limit the scope of the present disclosure. Each of the above-described embodiments may be modified in various ways without departing from the scope and gist of the present disclosure. For example, some configuration elements in one embodiment are able to be added to another embodiment. In addition, some configuration elements in one embodiment are able to be replaced with corresponding configuration elements in another embodiment.

What is claimed is:

1. An etching method, comprising:
(a) providing a substrate on a substrate support in a chamber, the substrate having a carbon-containing film and a mask on the carbon-containing film; and
(b) etching the carbon-containing film using plasma formed from a first processing gas, the first processing gas containing a phosphorus halide gas, an oxygen-containing gas, and a sulfur-containing gas, or containing the phosphorus halide gas and an oxygen- and sulfur-containing gas.

2. The etching method according to claim 1, further comprising:
(c) etching the carbon-containing film using plasma formed from a second processing gas different from the first processing gas, the second processing gas containing the oxygen-containing gas and the sulfur-containing gas, or containing the oxygen- and sulfur-containing gas.

3. The etching method according to claim 2, wherein the second processing gas does not include the phosphorus halide gas.

4. The etching method according to claim 2, wherein the second processing gas includes the phosphorus halide gas at a flow rate lower than a flow rate of the phosphorus halide gas included in the first processing gas.

5. The etching method according to claim 2, wherein a ratio of an execution time of the etching in the (c) to an execution time of the etching in the (b) is 0.8 or more and 1.2 or less.

6. The etching method according to claim 2, wherein a cycle including the (b) and the (c) is repeated a plurality of times.

7. The etching method according to claim 6, wherein, in at least one cycle of a second or subsequent cycles, a ratio of an execution time of the etching in the (c) to an execution time of the etching in the (b) is larger than the ratio in a first cycle.

8. The etching method according to claim 6, wherein a temperature of the substrate support in at least one cycle of a second or subsequent cycles is set to be higher than a temperature of the substrate support in a first cycle.

9. The etching method according to claim 1, wherein the phosphorus halide gas includes at least one gas selected from the group consisting of a fluorine halide gas, a chlorine halide gas, an oxyfluorine halide gas, and an oxychlorine halide gas.

10. The etching method according to claim 1, wherein the phosphorus halide gas includes at least one gas selected from the group consisting of a PF₃ gas, a PF₅ gas, and a PCl₃ gas.

11. The etching method according to claim 1, wherein, in the first processing gas, a flow rate of the phosphorus halide gas is 5 vol % or less of a total flow rate of the first processing gas.

12. The etching method according to claim 1, wherein the oxygen-containing gas includes at least one gas selected from the group consisting of an O₂ gas, a CO gas, and a CO₂ gas.

13. The etching method according to claim 1, wherein the oxygen- and sulfur-containing gas is at least one of a COS gas and an SO₂ gas.

14. The etching method according to claim 1, wherein the sulfur-containing gas is an SF₆ gas.

15. The etching method according to claim 1, wherein the mask includes a silicon-containing film or a metal-containing film.

16. The etching method according to claim 1, wherein the carbon-containing film includes an amorphous carbon film.

17. The etching method according to claim 1, wherein, in the (b), a temperature of the substrate support is set to 0° C. or lower.

18. The etching method according to claim 2, wherein, in the (c), a temperature of the substrate support is set to 0° C. or lower.

19. A plasma processing apparatus, comprising:
a chamber; and
a controller, wherein
the controller is configured to execute
(a) providing a substrate on a substrate support in a chamber, the substrate having a carbon-containing film and a mask on the carbon-containing film, and
(b) controlling of etching the carbon-containing film using plasma formed from a first processing gas, the first processing gas containing a phosphorus halide gas, an oxygen-containing gas, and a sulfur-containing gas, or containing the phosphorus halide gas and an oxygen- and sulfur-containing gas.

20. The plasma processing apparatus according to claim 19, wherein
the controller is configured to further execute
(c) etching the carbon-containing film using plasma formed from a second processing gas different from the first processing gas, the second processing gas containing the oxygen-containing gas and the sulfur-containing gas, or containing the oxygen- and sulfur-containing gas.
